(19) United States
(12) Patent Application Publication
(10) Pub. No.: US 2026/0085415 A1
(43) Pub. Date: Mar. 26, 2026

(54) System and Method for Delivering Liquid Precursor with a Constant Surface Level in a Ampoule to a Semiconductor Process Chamber

(71) Applicant: Yang Pan, SINGAPORE (SG)

(72) Inventor: Yang Pan, SINGAPORE (SG)

(73) Assignee: Inspiring Atoms Pte Ltd, SINGAPORE (SG)

(21) Appl. No.: 18/895,381

(22) Filed: Sep. 25, 2024

(51) Int. Cl. C23C 16/455; C23C 16/52

(52) U.S. Cl. CPC C23C 16/45544; C23C 16/52

(57) ABSTRACT

Disclosed herein is a vapor delivery system for semiconductor processes. The system includes an ampoule for storing and vaporizing a liquid precursor using a heater. A liquid level sensor within the ampoule monitors the surface level of the liquid precursor during a process step conducted in a process chamber. A controller regulates the rate at which the precursor is refilled from a precursor filling apparatus by adjusting the duty cycle of a square wave signal, which controls the on/off state of an atomic layer deposition (ALD) valve. This regulation ensures consistent precursor levels are maintained in the ampoule.

### FIELD OF THE INVENTION

This invention pertains to semiconductor device fabrication, specifically to systems and methods for the precise delivery and control of liquid precursors to a process chamber. The invention addresses challenges associated with the accurate delivery of liquid precursor volumes and encompasses designs of ampoules, valves, heaters, and control mechanisms related to precursor delivery in semiconductor manufacturing processes.

### BACKGROUND

Semiconductor device fabrication involves numerous material deposition or etching steps on substrates. These steps may utilize multiple precursors to form or remove a desired deposition layer within a process chamber. Precursors can exist in various states, such as gas, liquid, or solid. An efficient precursor delivery system that accurately controls the amount delivered to the process chamber is crucial.

### SUMMARY

This Summary introduces certain concepts in a simplified manner, which are elaborated in the Detailed Description that follows. This section neither identifies key nor essential features of the claimed subject matter and should not restrict the scope of the claimed subject matter.

In certain embodiments, a semiconductor process system includes a process chamber and a vapor delivery system. This chamber processes a substrate housed on a pedestal and includes a precursor delivery unit, such as a showerhead. Accurate control of the liquid precursor's volume entering the chamber is vital. A vapor delivery system, using a carrier gas, introduces the vaporized liquid precursor into the chamber. A longstanding challenge in the semiconductor manufacturing is the precise control of the liquid precursor volume delivered during a process step. Inconsistency in delivered volume can lead to process control issues, such as varied deposited film thicknesses.

In some implementations, a liquid precursor is housed in an ampoule. The ampoule's inner sidewall houses a liquid pressure sensor. Additionally, a heater is employed to vaporize the liquid precursor.

The liquid precursor is filled until the measured pressure from the pressure sensor hits a predetermined value. A carrier gas, like argon, flows into the ampoule, transporting the precursor vapor to the chamber. The ampoule connects to a precursor filling apparatus through a valve. In one design, this valve is an atomic layer deposition (ALD) valve known for its rapid response time, often in milliseconds. A controller governs the valve through an electrical signal, possibly a square wave produced by a pulse generator. The controller can adjust the square wave's frequency and/or duty cycle based on the anticipated precursor usage for the process step.

Once the process step begins, the vapor is discharged from the ampoule to the chamber. The pressure sensor routinely measures the pressure at set intervals. This measured pressure reflects the liquid precursor's surface level. Depending on the pressure during the process step, the controller alters the duty cycle to either increase or decrease the precursor volume delivered to the ampoule. For instance, a pressure reading below the preset value prompts an increase in the precursor volume, whereas a reading above this value results in a reduction.

In another set of embodiments, a software program within the controller calculates the volume of the precursor delivered to the ampoule at any given process step. This calculation derives from data provided by the liquid flow meter and the frequency and duty cycle of the square wave.

In a different embodiment, the computed precursor volume used in the process step determines the ending time of the process step.

In yet other embodiments, duration for a particular process step is fixed. The accurately controlled liquid precursor level in the ampoule enables amount of the precursor to be delivered to the chamber precisely.

In yet still other embodiments, a heater warms the liquid precursor inside the ampoule. In one design, this heater is resistive, and the ampoule is metallic, possibly stainless steel.

In other instances, the heater is optical, employing light to heat the liquid precursor's surface. Such a heater could be an array of light-emitting diodes, or a lamp placed above the liquid precursor.

Lastly, in some embodiments, the optical heater uses ultraviolet light to solely heat the liquid precursor's surface.

### BRIEF DESCRIPTION OF THE DRAWINGS

FIG. 1: A schematic of a semiconductor process system featuring a process chamber, vapor delivery system, and an ampoule connected through a valve.

FIG. 2A: A schematic of a vapor delivery system with an embedded liquid pressure sensor and a resistive heater.

FIG. 2B: A schematic of a vapor delivery system with an optical heater positioned above the liquid precursor.

FIG. 3: A functional diagram of a vapor delivery system.

FIG. 4: A flowchart detailing the process of maintaining a consistent precursor surface level in a vapor delivery system.

### DETAILED DESCRIPTIONS

In the subsequent detailed exposition of the present invention, specific implementations are outlined to facilitate a comprehensive grasp of the invention. However, it should be evident to those skilled in the art that the invention can be realized without these particulars or by employing different elements or methods. In certain cases, well-understood processes, procedures, and components are not elaborated upon to avoid obscuring the essence of the present invention unnecessarily.

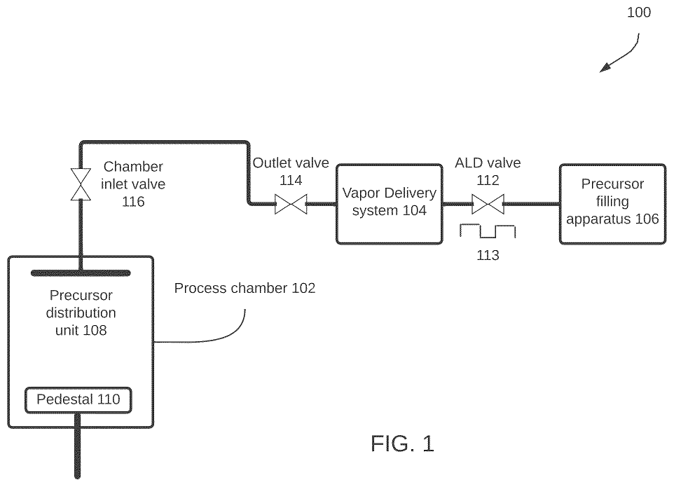

An exemplary semiconductor process system is depicted in FIG. 1. The system, labeled 100, incorporates a process chamber 102. This chamber is coupled to a vapor delivery system 104, through which a vaporized liquid precursor, carried by a typically inert carrier gas (like argon), is delivered to the process chamber 102. The vapor delivery system 104 is also connected to a precursor filling apparatus 106 via an ALD valve 112. This ALD valve boasts a rapid switching capability, typically within milliseconds. ALD valve 112's switching actions are directed by an electrical signal—specifically, a square wave 113 defined by its frequency and duty cycle. The volume of the liquid precursor transported from the precursor filling apparatus 106 to the vapor delivery system 104 is contingent on the duty cycle of this square wave. The system 100 aims to minimize process performance discrepancies by dispensing an exact quantity of the precursor during the substrate processing phase within the chamber.

Various embodiments ensure that the liquid precursor's surface level within an ampoule remains constant during the process step performed in the chamber 102. A noteworthy advantage here is that each substrate undergoes processing under almost identical ampoule conditions. For instance, the ampoule's headspace remains consistent for each substrate during a specific process. Conventional methods might encounter discrepancies in the liquid precursor's delivery due to variations in factors like the carrier gas flow, headspace pressure, and precursor surface temperature.

The chamber 102 is further equipped with a precursor distribution unit 108. Depending on the implementation, this unit can either be a showerhead or an injector. It's vital to acknowledge that various precursors and gases might be required for a specific process within the chamber 102, necessitating a custom design for the distribution unit 108. Additionally, the chamber 102 features a pedestal 110, serving to secure the substrate being processed. This pedestal can either be an electrostatic chuck or a vacuum chuck in different implementations. Valves, specifically valve 114 and valve 116 (as illustrated in FIG. 1), facilitate the connection of the vapor delivery system 104 to the process chamber 102.

Considering different implementations: the process chamber 102 can be a thermal process system, such as a thermal chemical vapor deposition (CVD) or a thermal atomic layer deposition (ALD) system. Alternatively, it might be a plasma-enhanced system like the plasma enhanced chemical vapor deposition (PECVD) or plasma enhanced atomic layer deposition (PEALD) systems. In another implementation, it can be a reactive ion etching (RIE) system or an atomic layer etching (ALE) system.

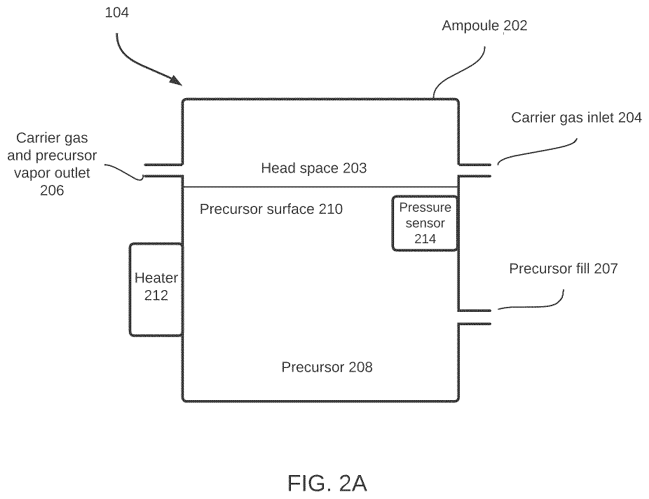

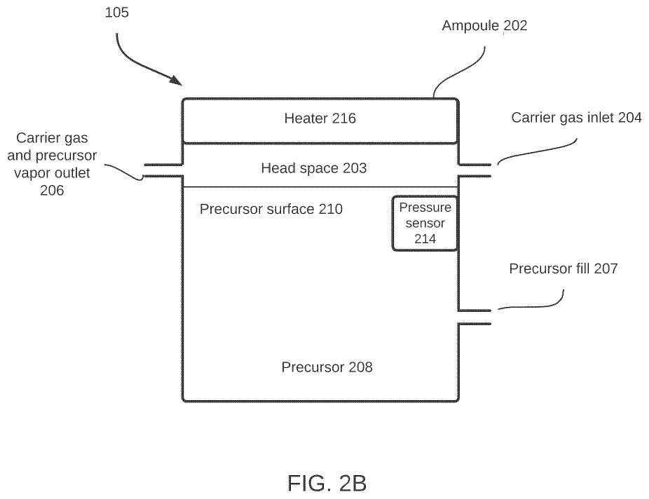

An embodiment of the vapor delivery system, denoted as 104, is illustrated in FIG. 2A. This system, 104, comprises an ampoule 202 designated for storing a liquid precursor. This precursor is then discharged to the chamber 102, where a substrate stationed on the pedestal 110 undergoes processing. The construction material of ampoule 202 can vary, including options like stainless steel, aluminum, quartz, plastic, and ceramics.

The vapor delivery system 104 is linked to a gasbox via a carrier gas inlet 204. Though not depicted in FIG. 2A, a valve typically governs the flow of the carrier gas, switching it on or off. Moreover, the vapor delivery system 104 communicates with the chamber 102 through an outlet 206, facilitating the transport of a mixture of carrier gas and the vaporized liquid precursor.

Further connectivity is established between the vapor delivery system 104 and the precursor filling apparatus 106 through an additional precursor inlet, 207. This apparatus, 106, refills the ampoule 202 with liquid precursor 208 up to a level defined by the precursor surface 210. The headspace 203, situated above the liquid precursor surface 210, ensures the carrier gas navigates through the ampoule 102, subsequently conveying the vaporized liquid precursor to the chamber 102.

The stored liquid precursor 208 within ampoule 202 can be elevated to a specific temperature with the aid of a heater 214. In this particular embodiment, a resistive heater is employed as heater 214. Uniform heating of the liquid precursor is favored. Given a scenario where the ampoule 202 features a metallic casing, the resistive heater 214 can ensure a consistent temperature distribution across the metal. Though absent in FIG. 1A, a temperature sensor can gauge the temperature of the liquid precursor 208. Using a control loop, one can maintain a steady temperature for the liquid precursor 208. Vaporization of the liquid precursor 208 necessitates its surface temperature to attain its boiling point.

In this described model, a pressure sensor 216 is mounted on the sidewall of the ampoule 202. The vertical alignment of the pressure sensor 216 demands precision. Prior to initiating a process step, the ampoule 202 is replenished with liquid precursor 208 to a level surpassing that of the pressure sensor 216. Consequently, the readings from the pressure sensor 216 become indicative of the surface level above the sensor. Calibration of the pressure sensor 216 readings against the precursor surface levels plays a pivotal role in ascertaining accurate measurement of the consumed liquid precursor.

Various implementations of the pressure sensor 216 exist, with options encompassing piezoresistive, capacitive, and optical designs, each exploiting distinct methodologies for meticulous pressure measurement. To detect minute pressure alterations in a liquid, a capacitive pressure sensor offers superior sensitivity.

FIG. 2B illustrates another embodiment of the vapor delivery system, labeled as 105. In this implementation, an optical heater 216 replaces the resistive sensor 212 showcased in FIG. 2A. Positioned above the precursor surface 210, the optical heater 216 maintains a distance ranging from 0.1 to 10 cm away from it. In a specific implementation, this heater is implemented as an LED heater array. This array finds its placement on a substrate, which integrates into the top section of the ampoule 202. Facing the top surface 210 of precursor 208, heater 216 draws power from a supply that is absent in FIG. 2A.

This embodiment utilizes on light-emitting heaters to elevate the temperature of the liquid precursor surface 210. The underlying principle hinges on the absorption of light energy by liquid molecules. As the light contacts the liquid's surface, its energy undergoes conversion to heat when molecules absorb the photon's energy. Consequently, molecule vibrations intensify, leading to temperature augmentation. Once this temperature hits the boiling point, a thin layer of the liquid transitions into vapor. The efficiency of absorption pivots on both the liquid's properties and the light's wavelength. To optimize surface absorption, the emitted light from heater 116 can be specifically tailored. In certain instances, heater 116 radiates ultraviolet (UV) light, notable for its comparably superficial absorption depth relative to visible light. Consequently, the energy conversion predominantly unfolds on or near the surface. With only a minute surface layer subjected to heating, the efficiency is commendable. Varying the power channeled to the LED heater array induces alterations in the temperature of precursor surface 210. In a separate variant of this embodiment, heater 216 takes the form of a lamp equipped with a flat surface, potentially offering a more economical alternative to the LED heater array. In a specific adaptation, this lamp emanates ultraviolet light.

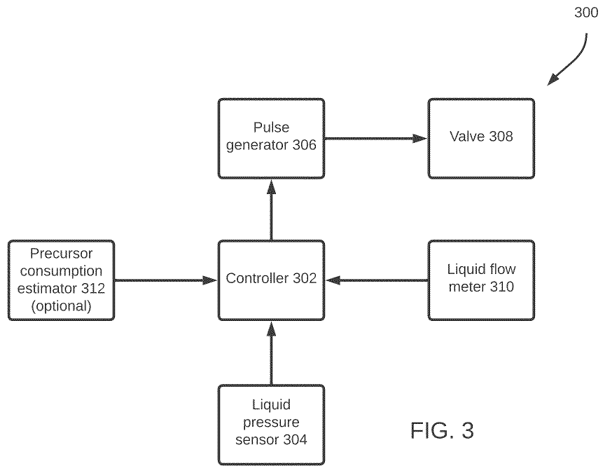

FIG. 3 portrays a functional schematic of the vapor delivery system, tagged as 300. At its core, system 300 integrates a controller 302. Depending on the implementation, controller 302 could be either a standalone computer or a component of the controller for the process system 100. Further, a pressure sensor 304 is placed within ampoule 202. Via the pulse generator 306, controller 302 dictates the valve 308's actions. This pulse generator 306 yields a square wave, distinguished by its frequency and duty cycle. Modulation of the rate of the liquid precursor dispatched from the precursor filling apparatus 206 to ampoule 202 is attainable through duty cycle adjustments. By analyzing measurements from pressure sensor 304, the controller amends the duty cycle to consistently maintain the liquid precursor surface 210 within ampoule 202. In addition, system 300 features a liquid flow meter 310, positioned between the vapor delivery system 104 and the precursor filling apparatus 106. System 300 may also integrate a precursor consumption estimator, labeled as 312. This estimator, housed within controller 302, can manifest as either software or a combined blend of software and firmware. It estimates the precursor amount utilized during a process step, drawing from readings of the liquid flow meter 310 and the waveform produced by the pulse generator 306. In certain configurations, the inferred precursor consumption might dictate the termination of the process step inside process chamber 102.

In another implementation, the starting and the ending time of a process step is fixed. Controlling precisely the liquid precursor surface level enables the amount of the precursor delivered to the process chamber accurately during the fixed process time. The variations caused by changes of headspace can be readily eliminated.

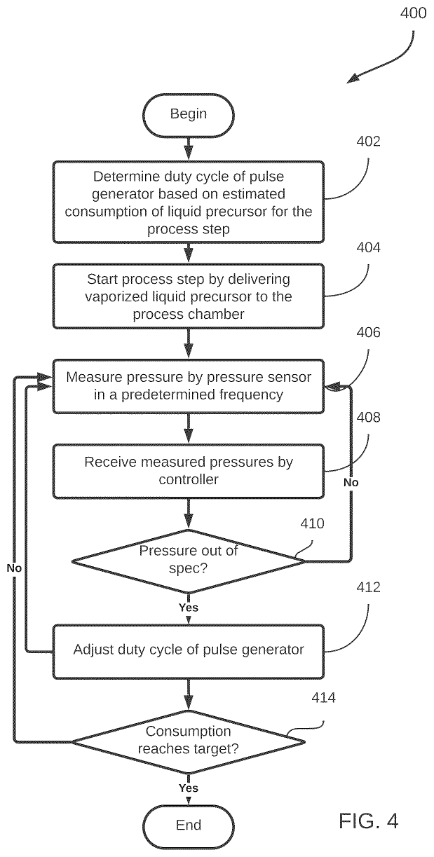

FIG. 4 shows a flow diagram illustrating process 400 of an exemplary vapor delivery system. In step 402, duty cycle of a square wave generated by pulse generator 306 is determined by controller 302. Selection of the duty cycle is based on replenishing an equal amount of liquid precursor consumed during the process step in the process chamber. After the duty cycle is selected, the process step 404 starts by delivering vaporized liquid precursor to the chamber 102. At the start of the process step, ampoule 202 is charged up to a surface level where pressure sensor 304 reads out a predetermined set value associated with the precursor surface level. Simultaneously, the replenishment of the precursor begins by delivering liquid precursor from precursor filling apparatus 106 to the vapor delivery system 104. The delivery rate is governed by the duty cycle, controlling the switching-on time of the ALD valve. In step 406, pressure from pressure sensor 304 is measured at a predetermined frequency. In step 410, controller 302 assesses if the readout from the pressure sensor exceeds the control limit (range). If the control limit is surpassed, the duty cycle is adjusted by controller 302 accordingly.

In one implementation, the consumption of the precursor up to the current point in time is computed in step 414 (optional). If the consumption reaches a targeted amount, the process step concludes in the process chamber 102.

1. A liquid precursor delivery system, comprising:
an ampoule configured to store a liquid precursor, equipped with an inlet for a carrier gas and an outlet to discharge the carrier gas combined with the vaporized precursor to a process chamber;
a liquid pressure sensor placed within the liquid precursor to gauge its level in the ampoule during a process step;
a heater configured to raise the temperature of the liquid precursor; and
a controller configured to control liquid precursor introduction into the ampoule from a precursor filling apparatus, wherein the controller determines the rate of the introduction via a valve, controlled by an electrical signal with a square wave via varying its duty cycle based upon an output of the pressure sensor.

2. The system of claim 1, wherein the precursor filling apparatus is further connected to a liquid flow meter.

3. The system of claim 1, wherein the controller includes a software module designed to compute the quantity of precursor transferred to the ampoule, based on the square wave and readings from a liquid flow meter.

4. The system of claim 1, wherein amount of the liquid precursor delivered to the process chamber is determined by the duration of a process step.

5. The system of claim 1, wherein the liquid pressure sensor is affixed at a predetermined location within the ampoule.

6. The system of claim 1, wherein the heater is of a resistive type.

7. The system of claim 1, wherein the heater employs optical heating techniques.

8. The system of claim 7, wherein the optical heater encompasses an LED array positioned above the surface of the liquid precursor.

9. The system of claim 8, wherein the LED array emits ultraviolet light.

10. The system of claim 7, wherein the optical heater comprises a lamp situated above the precursor surface.

11. The system of claim 10, wherein said lamp is designed to release ultraviolet light.

12. The system of claim 1, wherein the valve is an ALD valve.

13. A method for delivering liquid precursor from an ampoule to a process chamber during a process step, comprising:
filling the ampoule with liquid precursor from a precursor filling apparatus until a predetermined level, as indicated by a liquid pressure sensor, is achieved to initiate a process step;
employing a controller to establish the duty cycle of a square wave, which controls on/off state of a valve, wherein the valve regulates the flow rate between the ampoule and a precursor filling apparatus;
directing by the controller vaporized precursor combined with a carrier gas from the ampoule to the process chamber;
periodically assessing the pressure via the pressure sensor; and
adjusting the duty cycle of the square wave via the controller to ensure the assessed pressure remains consistent with the predetermined level.

14. The method of claim 13, further incorporating the step of gauging the flow rate of the liquid precursor via a flow meter situated between the precursor filling apparatus and the ampoule.

15. The method of claim 14, wherein an additional step involves using a software module in the controller to calculate the volume of precursor transferred to the ampoule, based on readings from the flow meter and the adjusted duty cycle of the square wave.

16. The method of claim 15, adding the step of concluding the process step in the chamber based on the determined volume of transferred precursor.

17. The method of claim 13, wherein the valve is an ALD valve.

18. A semiconductor process system, comprising:
a process chamber including a precursor distribution unit and a pedestal designed for substrate placement;
a liquid precursor delivery system; and
a controller configured to introduce liquid precursor into the ampoule from a precursor filling apparatus, wherein the controller determines rate of the liquid precursor introduction via a valve by varying duty cycle of a square wave based upon output of the pressure sensor.

19. The system of claim 18, wherein the ampoule further includes a liquid pressure sensor, wherein the controller varying the duty cycle of the square wave to maintain a constant output of the pressure sensor.

20. The system of claim 19, wherein the ampoule further includes a heater, wherein the heater is resistive or optical.
